(19) United States
(12) Patent Application Publication
(10) Pub. No.: US 2008/0176384 A1
(43) Pub. Date: Jul. 24, 2008

(54) Methods of forming impurity regions in semiconductor devices

(76) Inventor: Kyung-Seok Ko, Gyeonggi-do (KR)

Correspondence Address: MYERS BIGEL SIBLEY & SAJOVEC, PO BOX 37428, RALEIGH, NC, 27627, US

(21) Appl. No.: 12/009,541

(22) Filed: Jan. 18, 2008

(30) Foreign Application Priority Data
Jan. 18, 2007 (KR) 2007-005476

(51) Int. Cl. H01L 21/322

(52) U.S. Cl. 438/476; 257/E21.317

(57) ABSTRACT

Provided according to some embodiments of the present invention are methods of forming an impurity region in a semiconductor device. Such methods may include forming a pad oxide layer on a substrate; providing impurities to the substrate to form a preliminary impurity region in the substrate; performing a heat treatment process on the substrate while providing oxygen gas and an inert gas to the substrate; and removing the pad oxide layer. Methods according to embodiments of the invention may reduce pitting of the silicon substrate upon removal of the pad oxide layer.

### REFERENCE TO PRIORITY APPLICATION

This application claims priority under 35 USC § 119 to Korean Patent Application No. 2007-005476, filed on Jan. 18, 2007, which is herein incorporated by reference in its entirety.

### FIELD OF THE INVENTION

The present invention relates to methods of forming impurity regions in semiconductor devices.

### BACKGROUND OF THE INVENTION

Metal-oxide-semiconductor (MOS) transistors may serve as switching elements in semiconductor devices. The MOS transistor typically includes a gate on a substrate and a source/drain region at an upper portion of the substrate that is adjacent to the gate. A channel region may be formed at an upper portion of the substrate beneath the gate. The channel region may be doped with impurities having a conductive type different from that of the source/drain region.

In some methods of manufacturing MOS transistors, an implantation process is performed on the substrate to define the channel region. For example, a p-well doped with p-type impurities may be formed on an upper portion of the substrate to form the channel region. Such a p-well may be formed by the following method. First, a pad oxide layer, which may prevent the substrate from being damaged during the implantation of the p-type impurities, may be formed on a substrate. The p-type impurities may then be implanted into the substrate on which the pad oxide layer is formed. As an example, boron trifluoride (BF₃) may be used to create p-type impurities. Next, a rapid thermal process (RTP) may be performed on the substrate, thus activating the impurities implanted into the substrate. Finally, the pad oxide layer may be removed from the substrate to form the p-well.

When the pad oxide layer is removed from the substrate, some or all of the top surface of the substrate may also be removed, a phenomenon commonly referred to as pitting. In some cases, when pitting occurs upon removal of the pad oxide layer, a square groove, e.g., a groove having a width of about 0.1 μm, may be formed in the top surface of the substrate.

When a transistor is formed on a substrate having pitting in its surface, the transistor may not operate effectively. Thus, the yield rate of a semiconductor device that includes such a transistor may be decreased.

### SUMMARY OF THE INVENTION

Provided according to some embodiments of the present invention are methods of forming an impurity region in a semiconductor device. Such methods may include forming a pad oxide layer on a substrate; providing impurities to the substrate to form a preliminary impurity region in the substrate; providing oxygen and an inert gas, such as nitrogen, to the pad oxide layer and/or substrate while performing a heat treatment process thereon; and removing the pad oxide layer.

In some embodiments of the invention, contaminants in the pad oxide layer that result from providing of impurities to the substrate are prevented from entering the substrate. In addition, in some embodiments, the heat treatment process activates the impurities in the preliminary impurity region to form an impurity region in the substrate.

In some embodiments of the invention, the pad oxide layer includes a silicon oxide. In particular embodiments, the pad oxide layer is formed by a thermal oxidation process and/or a chemical vapor deposition (CVD) process. Additionally, in particular embodiments, the pad oxide layer has a thickness in a range of about 70 Å to about 200 Å.

In some embodiments of the invention, the oxygen gas has a flux of about 0.5% to about 10% of that of the inert gas. Additionally, in some embodiments, the heat treatment process is performed at a temperature in a range of about 900° C. to about 1,100° C. Furthermore, in some embodiments, the heat treatment process is performed for a time in a range of about 1 second to about 30 seconds.

In some embodiments of the invention, removing the pad oxide layer includes performing a wet etching process.

Also provided according to some embodiments of the present invention are methods of forming an impurity region in a semiconductor device that may include forming a first pad oxide layer on a substrate; providing impurities to the substrate to form a preliminary impurity region in the substrate; removing an upper portion of the pad oxide layer to form a second pad oxide layer; performing a heat treatment process on the substrate and remaining portion of the pad oxide layer; and removing the second pad oxide layer.

In some embodiments of the invention, the removal of the upper portion of the first pad oxide layer removes contaminants generated in the upper portion of the pad oxide layer during the providing of the impurities.

In some embodiments, the heat treatment process activates the impurities in the preliminary impurity region to form an impurity region in the substrate. In some embodiments, the heat treatment process includes providing an inert gas, such as nitrogen, to the substrate and/or pad oxide layer. In some embodiments, the heat treatment process is performed at a temperature in a range of about 900° C. to about 1,100° C. Furthermore, in some embodiments, the heat treatment process is performed for a time in a range of about 1 second to about 30 seconds.

In some embodiments of the invention, removing the upper portion of the first pad oxide layer includes performing a wet etching process. In some embodiments, removing the second pad oxide layer includes performing a wet etching process.

According to some embodiments of the invention, pitting of the substrate resulting from contaminants present in the pad oxide layer may be reduced or eliminated.

### BRIEF DESCRIPTION OF THE DRAWINGS

The above and other features and advantages of the present invention will become more apparent by describing in further detail exemplary embodiments of the invention, with reference to the accompanying drawings, in which:

FIGS. 1 to 4 are cross-sectional views illustrating methods of forming an impurity region in accordance with some embodiments of the present invention;

FIGS. 5 to 8 are cross-sectional views illustrating methods of forming an impurity region in accordance with some embodiments of the present invention;

FIG. 9 is a plan view illustrating a wafer map of a silicon substrate in which an impurity region is formed by a conventional method; and

FIG. 10 is a plan view illustrating a wafer map of a silicon substrate in which an impurity region is formed by a method according to an embodiment of the invention.

### DETAILED DESCRIPTION OF EXEMPLARY EMBODIMENTS OF THE INVENTION

The present invention is described more fully hereinafter with reference to the accompanying drawings, in which exemplary embodiments of the present invention are shown. The present invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, the exemplary embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be explained in detail with reference to the accompanying drawings.

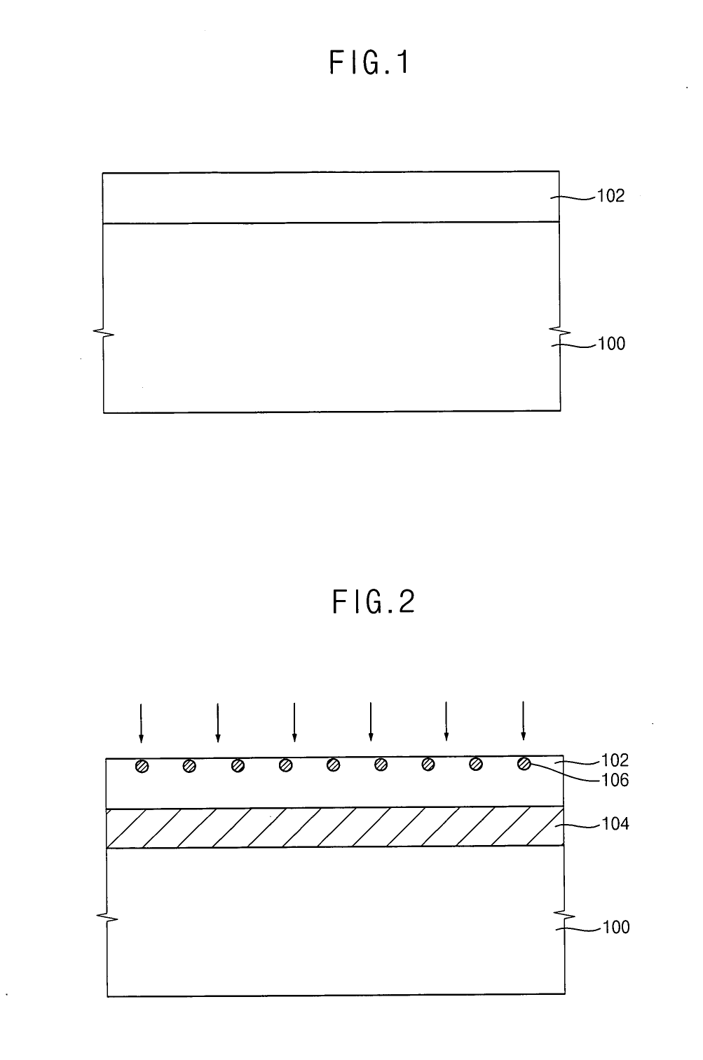

FIGS. 1 to 4 are cross-sectional views illustrating methods of forming an impurity region in accordance with some embodiments of the present invention. Methods of forming an impurity region that may serve as a channel region of an n-type MOS (NMOS) transistor will be described below. Such methods may be performed entirely, or in part, in one or more chambers.

Referring to FIG. 1, a shallow trench isolation (STI) process may performed on a silicon substrate 100 to form an isolation layer (not shown) at an upper portion of the silicon substrate 100. An active region and a field region may then be defined by the isolation layer. A pad oxide layer 102 may then be formed on the silicon substrate 100. The pad oxide layer 102 may prevent the surface of the silicon substrate 100 from being damaged when an ion implantation process is performed thereon. Additionally, the pad oxide layer 102 may control the depth of the doping of impurities into the silicon substrate 100 by the ion implantation process.

In some embodiments of the invention, the pad oxide layer 102 includes a silicon oxide. As an example, the pad oxide layer 102 may be formed by a thermal oxidation process on the silicon substrate 100. As another example, the pad oxide layer 102 may be formed by a chemical vapor deposition (CVD) process.

When the pad oxide layer 102 has a thickness below about 70 Å, the pad oxide layer 102 may not sufficiently prevent the surface of the silicon substrate 100 from being damaged. When the pad oxide layer 102 has a thickness above about 200 Å, a relatively high energy may be needed to implant impurities into the silicon substrate 100. Thus, in some embodiments, the pad oxide layer 102 is formed such that its thickness is in a range of about 70 Å to about 200 Å. In particular embodiments, the pad oxide layer 102 is formed to have a thickness in a range of about 90 Å to about 110 Å.

Referring to FIG. 2, a photoresist pattern (not shown) may be formed on the pad oxide layer 102 to expose a portion of the pad oxide layer 102. Impurities may then be implanted into the portion of the pad oxide layer 102 exposed by the photoresist pattern and the upper portion of the silicon substrate 100 beneath the portion of the pad oxide layer 102, thereby forming a preliminary impurity region 104 in the upper portion of the silicon substrate 100. In some embodiments, the impurities are implanted by an ion implantation process. In some embodiments, the ion implantation process is performed using p-type impurity ion sources, such as boron trifluoride (BF₃).

When an ion implantation process is performed, the relatively high energy impurities implanted into the substrate 100 may break down silicon lattices in the upper portion of the silicon substrate 100, so that the preliminary impurity region 104 may become partially or completely amorphous. Specifically, impurities implanted into the silicon substrate 100 may collide with silicon atoms of the silicon substrate 100, thus breaking the silicon-silicon bonds. Accordingly, silicon lattices in the upper portion of the silicon substrate 100 may become damaged, thus changing at least a portion of the preliminary impurity region 104 from a crystalline state to an amorphous state.

When such an ion implantation process is performed, contaminants 106 may form in a portion of the pad oxide layer 102. The contaminants 106 may be provided to the pad oxide layer 102 with the impurity ions. Specifically, contaminants 106 may lose energy upon collision with the pad oxide layer 102, so that the contaminants 106 may be present in a portion, typically the upper portion, of the pad oxide layer 102.

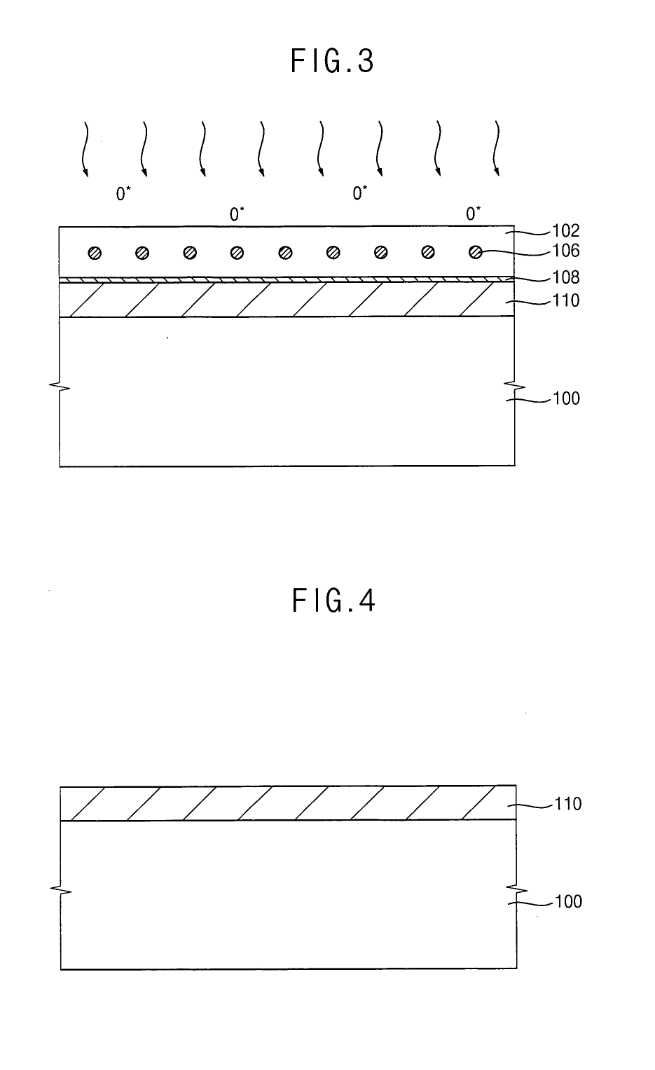

Referring to FIG. 3, oxygen (O₂) and an inert gas, such as nitrogen (N₂), may be provided to the pad oxide layer 102 and/or the silicon substrate 100, and a heat treatment process may be performed on the silicon substrate 100 and the pad oxide layer 102 thereon. Such a process may decrease or prevent the contaminants 106 in the pad oxide layer 102 from diffusing into the silicon substrate. The heat treatment process may also activate the impurities in the preliminary impurity region 104 (See FIG. 2).

During the heat treatment process, at least a portion of the preliminary impurity region 104 may change from the amorphous state to the crystalline state, and thus, impurities may move into the crystalline silicon lattices in the preliminary impurity region 104 so that the preliminary impurity region 104 becomes activated. As a result, an impurity region 110, which may have a relatively high conductivity, may be formed in the upper portion of the silicon substrate 100.

When the heat treatment process is performed at a temperature below about 900° C., the impurities may not be sufficiently activated. When the heat treatment process is performed at a temperature above about 1,100° C., the silicon substrate 100 may become damaged from heat. Additionally, when the heat treatment process is performed for less than about 1 second, the impurities may not be sufficiently activated, and when the heat treatment process is performed for more than about 30 seconds, the silicon substrate 100 may become damaged from the heat. Thus, in some embodiments of the invention, the heat treatment process is performed for a time in a range of about 1 second to about 30 seconds. In particular embodiments, when the heat treatment process is performed at a relatively low temperature, the heat treatment process may be performed for a relatively long time. Additionally, when the heat treatment process is performed at a relatively high temperature, the heat treatment process may be performed for a relatively short time. In particular embodiments of the present invention, the heat treatment process may be performed at a temperature of about 1,000° C. for about 10 seconds.

In conventional processes, contaminants 106 in the pad oxide layer 102 may diffuse into a top surface of the silicon substrate 100 when the heat treatment process is performed. As such, when the contaminants 106 diffuse into the top surface of the silicon substrate 100 and react with the silicon substrate 100, by-products may be generated on the top surface of the silicon substrate 100. When the pad oxide layer 102 is removed from the silicon substrate 100, the by-products may be also removed from the silicon substrate, which may result in pitting of the surface of the silicon substrate 100. Thus, in some embodiments of the present invention, the contaminants 106 do not diffuse, or may only slightly diffuse, into the surface of the silicon substrate 100 when the heat treatment process is performed.

In some embodiments of the present invention, oxygen gas and an inert gas, such nitrogen, are provided to the pad oxide layer 102 and/or silicon substrate 100 to prevent the contaminants 106 from being diffused into the silicon substrate 100 during the heat treatment process. Specifically, oxygen gas and an inert gas may be provided into a chamber wherein a heat treatment process is performed, and highly reactive oxygen radicals may be formed in the chamber. The inert gas may act to maintain the pressure and temperature in the chamber without being reactive toward the silicon substrate 100. The inert may also be exhausted from the chamber with any other gases.

Due to the relatively high reactivity of the oxygen radicals, a first portion of the oxygen radicals may readily infiltrate into the pad oxide layer 102 and react with the contaminants 106. Accordingly, such contaminants 106 may be prevented from diffusing into the silicon substrate 100. Additionally, a second portion of the oxygen radicals that has not reacted with the contaminants 106 may react with the surface of the silicon substrate 100, thereby forming a radical oxide layer 108. The radical oxide layer 108 may be formed at the top surface of the silicon substrate 100 before the contaminants 106 are able to diffuse to the surface of the silicon substrate 100, so that the contaminants 106 may not react with the surface of the silicon substrate 100.

As described above, in some embodiments of the invention, the contaminants 106 may not diffuse, or may only slightly diffuse, into the silicon substrate 100. Instead, the contaminants may remain in the pad oxide layer 102 when a heat treatment process is performed on the silicon substrate 100 and the pad oxide layer 102.

During the heat treatment process, when the oxygen gas has a flux greater than about 10% of that of the inert gas, the radical oxide layer 108 formed on the silicon substrate 100 may be relatively thick, so that the pad oxide layer 102 and the radical oxide layer 108 may not be readily removed from the silicon substrate 100. Meanwhile, when the oxygen gas has a flux of less than about 0.5% of that of the inert gas, the contaminants 106 may not be effectively prevented from diffusing into the silicon substrate 100. Thus, in some embodiments, the oxygen gas may have a flux of about 0.5% to about 10% of that of the inert gas during the heat treatment process. As used herein, this percentage is based on volumetric flow rates.

Referring to FIG. 4, the pad oxide layer 102 may be removed from the silicon substrate 100. Generally, the pad oxide layer 102 does not serve as a gate oxide layer of a transistor because the pad oxide layer 102 is typically damaged during the ion implantation process and may include residual contaminants 106. Thus, in some embodiments, a gate oxide layer may be formed on the silicon substrate 100 after the removal of the pad oxide layer 102.

In some embodiments of the invention, the pad oxide layer 102 is removed from the silicon substrate 100 by a wet etching process. Such processes generally do not damage the silicon substrate 100. In some embodiments, the pad oxide layer 102 may be removed by a wet etching process using an etching solution including hydrogen fluoride (HF), ammonium fluoride (NH₄F), deionized water and/or other wet etching components known to those of skill in the art. Such components may be used alone or in any mixture thereof.

When the pad oxide layer 102 is removed, the contaminants 106 in the pad oxide layer 102 may also be removed. Thus, in some embodiments, contaminants 106 may not have reacted, or may have only slightly reacted with the silicon substrate 100, so that by-products may not be formed, or may only slightly be formed, on the silicon substrate 100. Accordingly, pitting of the surface of the silicon substrate 100 may not occur, or may be minimal, after removal of the pad oxide layer 102.

A silicon oxide layer (not shown), a gate electrode (not shown), and source/drain regions (not shown) may be formed on/in an upper portion of the silicon substrate 100, and thus an NMOS transistor may be formed on the silicon substrate 100.

As described above, pitting of a silicon substrate may be reduced or eliminated by adding oxygen and an inert gas to a pad oxide layer and/or silicon substrate during a heat treatment process. As such, in some embodiments, no additional processing of the silicon is necessary to prevent or reduce pitting of the substrate.

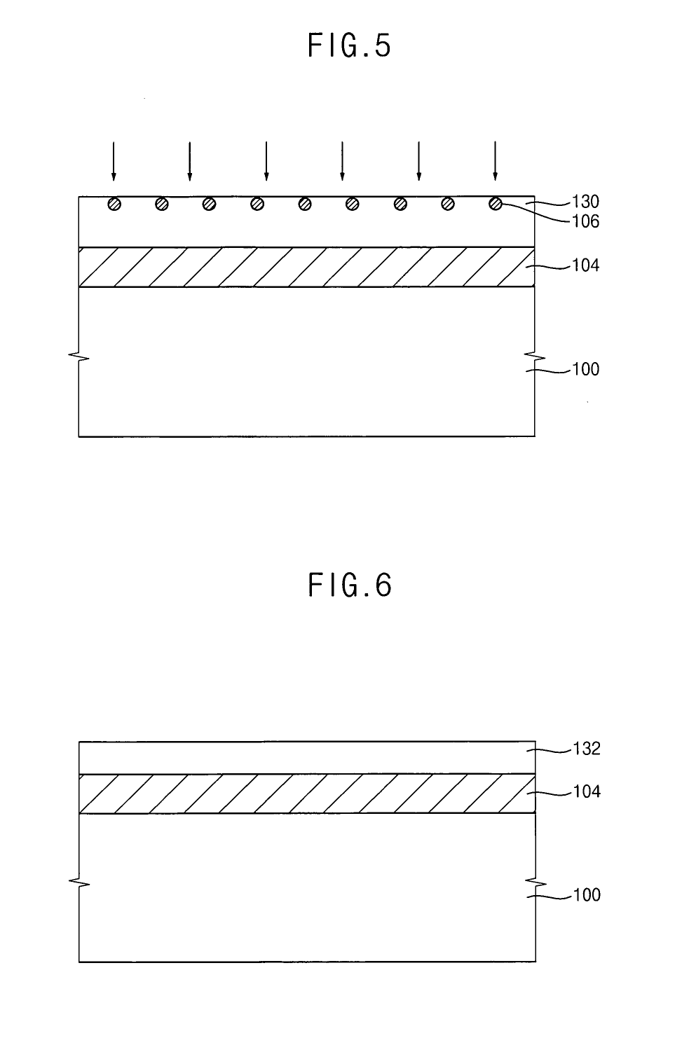

FIGS. 5 to 8 are cross-sectional views illustrating methods of forming an impurity region in accordance with other embodiments of the present invention.

Referring to FIG. 5, a first pad oxide layer 130 may be formed on the silicon substrate 100 including an isolation layer (not shown) thereon.

A photoresist pattern (not shown) may be formed on the first pad oxide layer 130 to expose a portion of the first pad oxide layer 130. Impurities may be implanted into the portion of the first pad oxide layer 130 exposed by the photoresist pattern and the portion of the silicon substrate 100 beneath the portion of the first pad oxide layer 130, thereby forming a preliminary impurity region 104 at the upper portion of the silicon substrate 100. In some embodiments, the impurities may be implanted by an ion implantation process.

When the ion implantation process is performed, contaminants 106 may form in a portion of the first pad oxide layer 130. The contaminants 106 may be provided to the first pad oxide layer 130 with the impurity ions. Specifically, the contaminants 106 may lose energy upon collision with the first pad oxide layer 130, so that the contaminants 106 may be present in a portion, typically the upper portion, of the pad oxide layer 130.

Referring to FIG. 6, the upper portion of the first pad oxide layer 130 may be removed to form second pad oxide layer 132 having a thickness of less than that of the first pad oxide layer 130, so that the contaminants 106 present in the upper portion of the first pad oxide layer 130 may be removed.

In some embodiments of the invention, the upper portion of the first pad oxide layer 130 may be removed by a wet etching process. In some embodiments, the upper portion of the first pad oxide layer 130 may be removed by a wet etching process using an etching solution including hydrogen fluoride (HF), ammonium fluoride (NH₄F), a deionized water, and/or other wet etching components known to those of skill in the art. Such components may be used alone or in any mixture thereof.

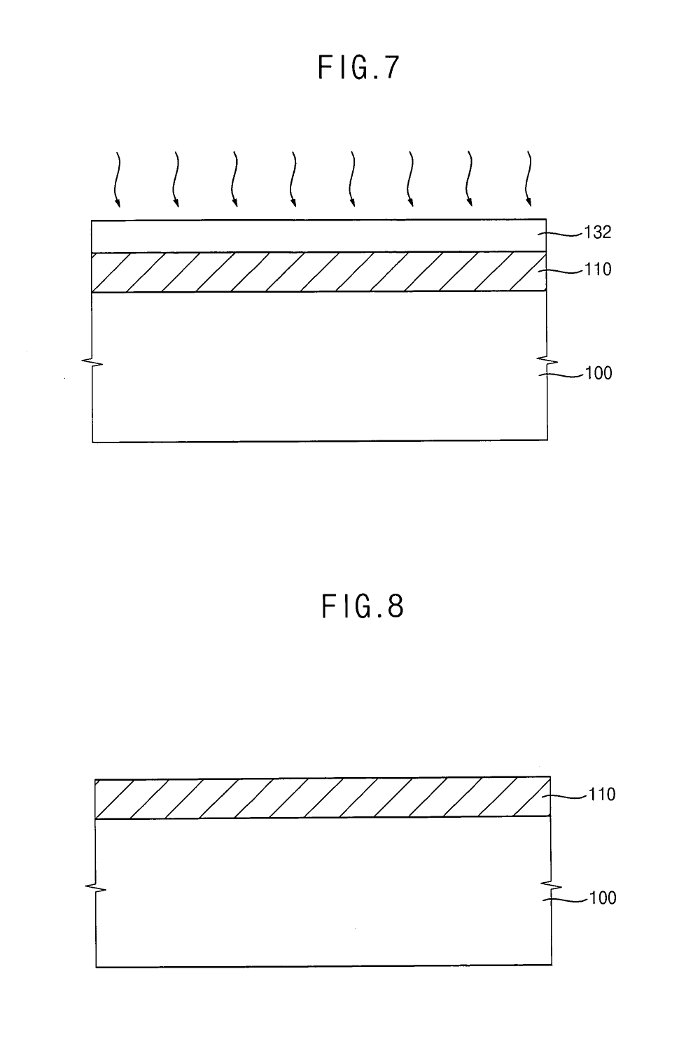

Referring to FIG. 7, a heat treatment process may then be performed on the silicon substrate 100 having the second pad oxide layer 132 thereon to activate the impurities. When the heat treatment process is performed, at least a portion of the preliminary impurity region 104 (see FIG. 6) may change from the amorphous state to a crystalline state, and thus, impurities may move into silicon lattices in the preliminary impurity region 104, so that the preliminary impurity region 104 may be activated. As a result, an impurity region 110, which may have a relatively high conductivity, may be formed in the upper portion of the silicon substrate 100.

In some embodiments of the invention, the heat treatment process may be performed at a temperature in a range of about 900° C. to about 1,100° C., and in some embodiments, for a time in a range of about 1 second to about 30 seconds. In some embodiments, when the heat treatment process is performed at a relatively low temperature, the heat treatment process may be performed for a relatively long time. Additionally, in some embodiments, when the heat treatment process is performed at a relatively high temperature, the heat treatment process may be performed for a relatively short time. In particular embodiments of the present invention, the heat treatment process is performed at a temperature of about 1,000° C. for a time of about 10 seconds.

In some embodiments of the invention, the contaminants 106 may not form, or may only be slightly formed, in the second pad oxide layer 132, so that the contaminants 106 may not diffuse into the surface of the silicon substrate 100 when a heat treatment process is performed. Accordingly, by-products formed by reaction between the contaminants 106 and the silicon substrate 100 may not be generated or may only be slightly generated. Thus, pitting of the silicon substrate 100 caused by such by-products may be reduced or eliminated.

During the heat treatment process, an inert gas, such as nitrogen, may be provided into a chamber containing the silicon substrate 100. The inert gas may be used to maintain the pressure and temperature in the chamber while not being reactive toward the silicon substrate 100. The inert gas may also be exhausted from the chamber with any other gases.

Referring to FIG. 8, the second pad oxide layer 132 may then be removed. For example, the second pad oxide layer 132 may be removed from the silicon substrate 100 by a wet etching process, which may reduce or eliminate damage to the silicon substrate 100. In some embodiments, the second pad oxide layer 132 may be removed by a wet etching process using an etching solution including hydrogen fluoride (HF), ammonium fluoride (NH₄F), a deionized water, and/or other wet etching components known to those of skill in the art. Such components may be used alone or in any mixture thereof.

### EXAMPLE

As described in further detail below, a silicon substrate having an impurity region formed by a method in accordance with an embodiment of the present invention, and a silicon substrate having an impurity region formed by a conventional method, were formed. Each silicon substrate was inspected; the results are described below.

### Example According to an Embodiment of the Invention

A pad oxide layer having a thickness of about 100 Å was formed on a substrate in a chamber. Impurities were implanted into the substrate on which the pad oxide layer was formed. The substrate was heated at a temperature of about 1,000° C. for about ten seconds to activate the impurities, while oxygen gas and nitrogen gas were provided into the chamber. The flow rate of the nitrogen gas was about 5 standard liters per minute (SLM) and the flow rate of the oxygen gas was about 0.5 SLM. Thus, the oxygen gas had a flux of about 10% of that of the nitrogen gas. The pad oxide layer was then removed by a wet etching process.

### Comparative Example

A pad oxide layer having a thickness of about 100 Å was formed on a substrate in a chamber. Impurities were implanted into the substrate on which the pad oxide layer was formed. The substrate was heated at a temperature of about 1,000° C. for about ten seconds to activate the impurities, while nitrogen gas was provided into the chamber. The pad oxide layer was removed by a wet etching process.

### Results

The top surface of the silicon substrate in the Comparative Example and the top surface of the silicon substrate in the Example according to an embodiment of the invention were examined.

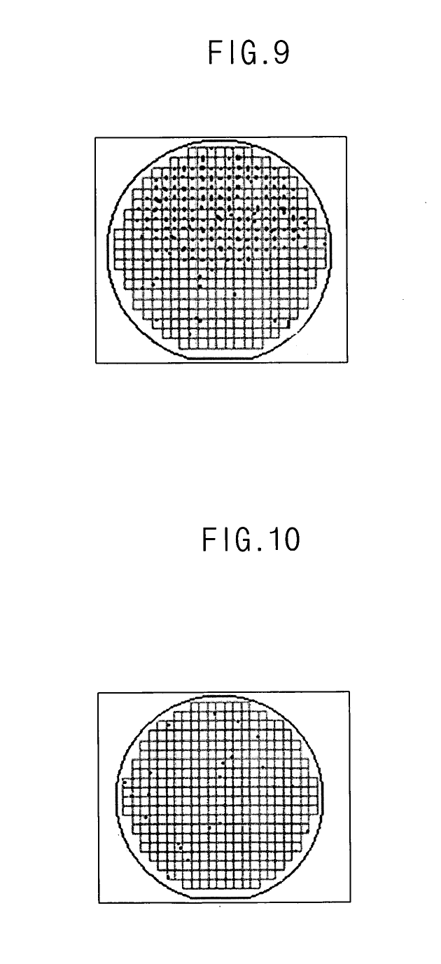

FIG. 9 is a plan view illustrating a wafer map of the silicon substrate in the Comparative Example. FIG. 10 is a plan view illustrating a wafer map of the silicon substrate in the Example according to an embodiment of the invention. The black spots in the wafer map represent failures in the silicon substrate.

Referring to FIG. 9, many failures were generated on the silicon substrate in the Comparative Example. Such failures were predominantly due to pitting of the top surface of the silicon substrate.

Referring to FIG. 10, relatively few failures were generated on the silicon substrate in the Example according to an embodiment of the invention, and pitting of top surface of the silicon substrate was not observed.

As described above, pitting of the top surface of a silicon substrate was remarkably reduced when an impurity region was formed in accordance with an embodiment of the present invention.

Accordingly, in some embodiments of the present invention, pitting resulting from the formation of an impurity region may be reduced or eliminated. Thus, the yield rate of a semiconductor device including the impurity region may be improved.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A method of forming an impurity region in a semiconductor device, the method comprising:
forming a pad oxide layer on a substrate;
providing impurities to the substrate to form a preliminary impurity region in the substrate;
providing oxygen and an inert gas to the pad oxide layer and/or the substrate while performing a heat treatment process thereon; and
removing the pad oxide layer.

2. The method of claim 1, wherein contaminants in the pad oxide layer that result from providing impurities to the substrate are prevented from entering the substrate.

3. The method of claim 1, wherein the heat treatment process activates the impurities in the preliminary impurity region to form an impurity region in the substrate.

4. The method of claim 1, wherein the pad oxide layer comprises a silicon oxide.

5. The method of claim 4, wherein the pad oxide layer is formed by a thermal oxidation process and/or a chemical vapor deposition process.

6. The method of claim 1, wherein the pad oxide layer has a thickness in a range of about 70 Å to about 200 Å.

7. The method of claim 1, wherein the inert gas comprises nitrogen gas.

8. The method of claim 1, wherein the oxygen gas has a flux of about 0.5% to about 10% of that of the inert gas.

9. The method of claim 1, wherein the heat treatment process is performed at a temperature in a range of about 900° C. to about 1,100° C.

10. The method of claim 1, wherein the heat treatment process is performed for a time in a range of about 1 second to about 30 seconds.

11. The method of claim 1, wherein removing the pad oxide layer comprises performing a wet etching process.

12. A method of forming an impurity region in a semiconductor device, the method comprising:
forming a first pad oxide layer on a substrate;
providing impurities to the substrate to form a preliminary impurity region in the substrate;
removing an upper portion of the first pad oxide layer to form a second pad oxide layer;
performing a heat treatment process on the substrate and the second pad oxide layer; and then
removing the second pad oxide layer.

13. The method of claim 12, wherein the removal of the upper portion of the first pad oxide layer removes contaminants generated in the upper portion of the first pad oxide layer that result from providing the impurities.

14. The method of claim 12, wherein the heat treatment process activates impurities in the preliminary impurity region to form an impurity region.

15. The method of claim 12, wherein the heat treatment process comprises providing an inert gas to the substrate and/or the second pad oxide layer.

16. The method of claim 14, wherein the inert gas comprises nitrogen gas.

17. The method of claim 12, wherein the heat treatment process is performed at a temperature in a range of about 900° C. to about 1,100° C.

18. The method of claim 12, wherein the heat treatment process is performed for a time in a range of about 1 second to about 30 seconds.

19. The method of claim 12, wherein removing the upper portion of the first pad oxide layer comprises performing a wet etching process.

20. The method of claim 12, wherein removing the second pad oxide layer comprises performing a wet etching process.
